(19) United States
(12) Patent Application Publication
(10) Pub. No.: US 2026/0327806 A1
(43) Pub. Date: Oct. 22, 2026

(54) METHOD FOR FORMING SILICON CARBIDE FILM

(71) Applicant: JUSUNG ENGINEERING CO., LTD., Gwangju-Si, Gyeonggi-Do (KR)

(72) Inventors: Gyeong Hun WON, Gwangju-Si, Gyeonggi-Do (KR); Chul Joo HWANG, Gwangju-Si, Gyeonggi-Do (KR)

(21) Appl. No.: 19/524,601

(22) PCT Filed: Oct. 14, 2024
(86) PCT No.: PCT/KR2024/015487

§ 371 Date: Mar. 30, 2026

(30) Foreign Application Priority Data
Oct. 16, 2023 (KR) 10-2023-0137705
Feb. 19, 2024 (KR) 10-2024-0023496

(51) Int. Cl. C23C 16/56; C23C 16/32; C23C 16/44; C23C 16/509; H01J 37/32; H10P 14/20; H10P 14/24

(52) U.S. Cl. CPC C23C 16/56; C23C 16/325; C23C 16/4408; C23C 16/509; H01J 37/32449; H01J 37/32834; H10P 14/24; H10P 14/3408; H10P 14/3454; H10P 14/3802; H01J 2237/332

(57) ABSTRACT

An exemplary embodiment of the present inventive concept provides a method for forming a silicon carbide film on a substrate accommodated in a chamber, wherein the method includes injecting a silicon (Si)-containing gas into the chamber, forming first hydrogen plasma inside the chamber while injecting a carbon (C)-containing gas into the chamber, thereby forming an amorphous silicon carbide film on the substrate, and forming second hydrogen plasma inside the chamber, thereby crystallizing the amorphous silicon carbide film.

Therefore, according to exemplary embodiments of the present inventive concept, it is possible to form a crystalline silicon carbide film at low temperatures. That is, it is possible to form a crystalline silicon carbide film with a few or no defects.

### TECHNICAL FIELD

The present disclosure relates to a method for forming a silicon carbide film, and more particularly, to a method for forming a silicon carbide film, the method capable of forming a silicon carbide film at low temperatures.

### BACKGROUND ART

A silicon carbide (SiC) film is formed by injecting a silicon (Si)-containing gas to a substrate, followed by injecting a carbon(C)-containing gas. At this time, the temperature inside a chamber should be raised to a high-temperature of approximately 1000 °C or higher by heating to form a crystalline silicon carbide film.

However, if a silicon carbide film is crystallized in a high-temperature environment of approximately 1000 °C or higher, there is a problem in that a large number of defects are generated in the silicon carbide film. Therefore, if a semiconductor device including a silicon carbide film is manufactured, a leakage current is generated due to the silicon carbide film.

### [Prior Art Document] (Patent Document 1)

Korean Patent Laid-Open Publication 10-2000-0068834.

### DISCLOSURE OF THE INVENTIVE CONCEPT

### Technical Problem

The present disclosure provides a method for forming a silicon carbide film with less generation of defects.

The present disclosure also provides a method for forming a silicon carbide film, the method capable of forming a crystalline silicon carbide film at low temperatures.

### Technical Solution

In accordance with an exemplary embodiment, a method for forming a silicon carbide film on a substrate accommodated in a chamber includes injecting a silicon (Si)-containing gas into the chamber, forming first hydrogen plasma inside the chamber while injecting a carbon (C)-containing gas into the chamber, thereby forming an amorphous silicon carbide film on the substrate, and forming second hydrogen plasma inside the chamber, thereby crystallizing the amorphous silicon carbide film.

The forming of the first and second hydrogen plasma may include supplying a hydrogen-containing gas into the chamber, wherein the first and second hydrogen plasma may be direct plasma formed by discharging the hydrogen-containing gas inside the chamber.

The forming of the first and second hydrogen plasma may include supplying an argon (Ar) into the chamber.

The forming of the first and second hydrogen plasma may include supplying RF power to the chamber, wherein the RF power may be approximately 800 W to approximately 900 W.

The forming of the first and second hydrogen plasma may include supplying RF power to the chamber, wherein the RF power may be approximately 2.66 W/cm² to approximately 3 W/cm² per unit area of the substrate.

In the forming of the first and second hydrogen plasma, the forming may be performed by using a potential difference between a first electrode and a second electrode installed inside the chamber.

The time for forming the second hydrogen plasma may be longer than the time for forming the first hydrogen plasma.

In the injecting of the silicon (Si)-containing gas, the forming of the amorphous silicon carbide film, and the crystallizing of the amorphous silicon carbide film, the temperature inside the chamber may be controlled to approximately 300 °C to approximately 700 °C.

The method may further include forming hydrogen plasma inside the chamber between the injecting of the silicon (Si)-containing gas and the forming of the first hydrogen plasma while injecting the carbon (C)-containing gas.

The method may further include at least one of a purge step of injecting a purge gas into the chamber, thereby purging the inside of the chamber, and a pumping step of discharging the gas inside the chamber to the outside, thereby lowering the pressure inside the chamber, wherein at least one of the purge step and the pumping step may be performed between the injecting of the silicon (Si)-containing gas and the forming of the first hydrogen plasma while injecting the carbon (C)-containing gas.

The method may further include at least one of a purge step of injecting a purge gas into the chamber, thereby purging the inside of the chamber, and a pumping step of discharging the gas inside the chamber to the outside, thereby lowering the pressure inside the chamber, wherein at least one of the purge step and the pumping step may be performed after completing the forming of the second hydrogen plasma inside the chamber, thereby crystallizing the amorphous silicon carbide film.

In accordance with another exemplary embodiment, a method for forming a silicon carbide film on a substrate accommodated in a chamber including a dome-shaped upper body having an inclined surface whose height increases toward the center in a width direction and a dome-shaped lower body having an inclined surface whose height decreases toward the center in the width direction includes injecting a silicon (Si)-containing gas into the chamber by using a first gas injection part connected to the chamber, forming first hydrogen plasma inside the chamber while injecting a carbon (C)-containing gas into the chamber by using a second gas injection part connected to the chamber, thereby forming an amorphous silicon carbide film on the substrate, and forming second hydrogen plasma inside the chamber, thereby crystallizing the amorphous silicon carbide film.

In accordance with yet another exemplary embodiment, a method for forming a silicon carbide film on a substrate accommodated in a chamber includes injecting a silicon (Si)-containing gas into the chamber through a first gas flow path provided in a first electrode installed in the chamber, forming first hydrogen plasma between the first electrode and a second electrode while injecting a carbon (C)-containing gas into the chamber through a second gas flow path provided in the second electrode installed in the chamber, thereby forming an amorphous silicon carbide film on the substrate, and forming second hydrogen plasma between the first electrode and the second electrode, thereby crystallizing the amorphous silicon carbide film.

In accordance with still another exemplary embodiment, a method for forming a silicon carbide film on a substrate accommodated in a chamber includes, in a support surface of a substrate support installed inside the chamber, seating the substrate in an outer region of the support surface, injecting a silicon (Si)-containing gas to the outer region of the support surface by using an opening provided in an injection part connected to the chamber and provided at a position corresponding to the outer region of the support surface, forming first hydrogen plasma inside the chamber while injecting a carbon (C)-containing gas to the outer region of the support surface by using the opening of the injection part, thereby forming an amorphous silicon carbide film on the substrate, and forming second hydrogen plasma inside the chamber, thereby crystallizing the amorphous silicon carbide film.

In accordance with yet still another exemplary embodiment, a method for forming a silicon carbide film on a substrate accommodated in a chamber includes seating the substrate on a support surface of a substrate support part installed inside the chamber, injecting a silicon (Si)-containing gas to the entire region of the support surface by using a first flow path provided in an injection part connected to the chamber and provided to inject a gas to the front surface of the support surface, forming first hydrogen plasma inside the chamber while injecting a carbon (C)-containing gas to the entire region of the support surface by using a second flow path provided in the injection part and provided to inject a gas to the front surface of the support surface, thereby forming an amorphous silicon carbide film on the substrate, and forming second hydrogen plasma inside the chamber, thereby crystallizing the amorphous silicon carbide film.

In accordance with yet still another exemplary embodiment, a method for forming a silicon carbide film on a substrate accommodated in a chamber including a first plate having a first opening and a second opening, a second plate electrically insulated from the first plate, spaced apart from the first plate, and having a plurality of third openings disposed alternately with the first opening and the second opening, and a turbo molecular pump (TMP) includes injecting a silicon (Si)-containing gas into the chamber by using the first opening connected to the chamber, forming first hydrogen plasma inside the chamber while injecting a carbon (C)-containing gas into the chamber by using the second opening connected to the chamber, thereby forming an amorphous silicon carbide film on the substrate, and forming second hydrogen plasma inside the chamber, thereby crystallizing the amorphous silicon carbide film.

The chamber including the turbo molecular pump (TMP) may be controlled to a pressure of approximately 10 mTorr to approximately 50 mTorr at a pressure of high vacuum.

The first opening may be connected from a gas storage unit, wherein the gas storage unit may be connected to the first opening to temporarily inject one or one or more gases.

The gas storage unit may include a pile-up tank, wherein the pile-up tank may be connected to a gas flow path to fill one or one or more gases, and may temporarily inject the filled gas.

### Advantageous Effects

According to exemplary embodiments of the present inventive concept, it is possible to form a crystalline silicon carbide film at low temperatures. That is, it is possible to form a crystalline silicon carbide film with a few or no defects.

### BRIEF DESCRIPTION OF THE DRAWINGS

FIG. 1 is a view illustrating a state in which a silicon carbide film is formed on a substrate by a method in accordance with an exemplary embodiment;

FIG. 2 is a view illustrating a state in which a silicon carbide film is formed on an underlayer formed on one surface of a substrate by the method in accordance with an exemplary embodiment;

(a) to (c) of FIG. 3 are process diagrams conceptually illustrating a method for forming a silicon carbide film on a substrate by the method in accordance with an exemplary embodiment;

FIG. 4 is a view schematically showing a first substrate processing apparatus for forming silicon carbide films in accordance with exemplary embodiments;

(a) to (d) of FIG. 5 are process diagrams conceptually illustrating a method for forming a silicon carbide film on a substrate by a method in accordance with another exemplary embodiment;

FIG. 6 is a view schematically showing a substrate processing apparatus of another embodiment capable of forming a silicon carbide film in accordance with an exemplary embodiment;

FIG. 7 is a schematic perspective view of a substrate support part in the substrate processing apparatus of another exemplary embodiment;

FIG. 8 is a plan view of a substrate support part in the substrate processing apparatus of another exemplary embodiment;

FIG. 9 is a schematic bottom view of an injection part in the substrate processing apparatus of another exemplary embodiment;

FIG. 10 is a schematic bottom view of an injection part in the substrate processing apparatus of another exemplary embodiment;

FIG. 11 is a schematic side-sectional view of an injection part in the substrate processing apparatus of another embodiment;

FIG. 12 is a flow chart schematically showing a method for forming the silicon carbide film in accordance with an exemplary embodiment by using the substrate processing apparatus of another exemplary embodiment; and

FIG. 13 is a side cross-sectional view of an injection part of the substrate processing apparatus of another exemplary embodiment.

### MODE FOR CARRYING OUT THE INVENTIVE CONCEPT

Hereinafter, embodiments of the present inventive concept will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. The drawings may be exaggerated to describe the embodiments of the present inventive concept.

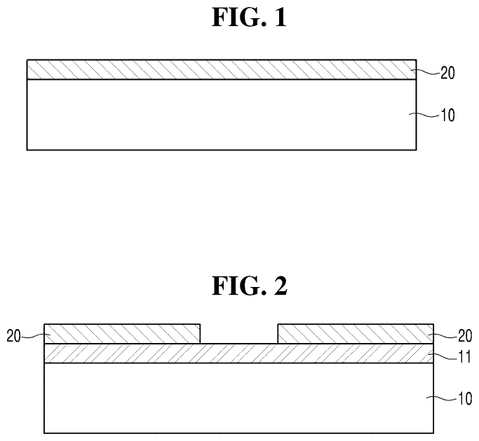

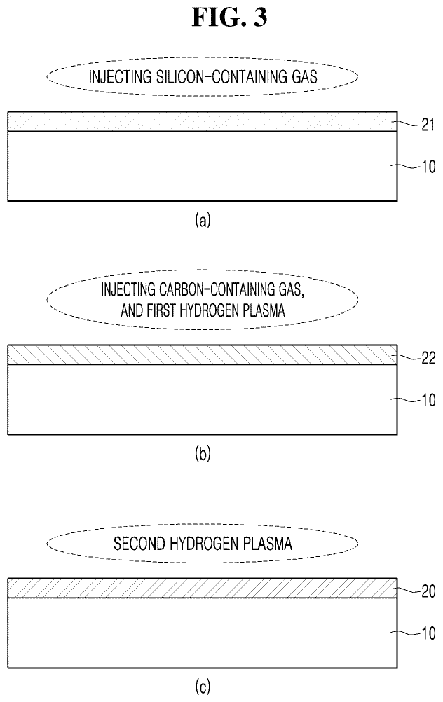

FIG. 1 is a view illustrating a state in which a silicon carbide film is formed on a substrate by a method in accordance with an exemplary embodiment. FIG. 2 is a view illustrating a state in which a silicon carbide film is formed on an underlayer formed on one surface of a substrate by the method in accordance with an exemplary embodiment.

Referring to FIG. 1, a silicon carbide film 20 may be formed on a substrate 10. The substrate 10 may be any one of a wafer, glass, and metal. If the substrate 10 is a wafer, the wafer may be, for example, any one of a silicon (Si) wafer, a silicon carbide (SiC) wafer, and a gallium arsenide (GaAs) wafer.

Referring to FIG. 2, a predetermined film (hereinafter, an underlayer 11) may be formed on at least one surface of the substrate 10, and a silicon carbide film 20 may be formed on the underlayer 11. In this case, the silicon carbide film 20 may be formed, for example, for a hard mask. That is, in forming the silicon carbide film 20 on the underlayer 11, the silicon carbide film 20 is formed such that a portion of the underlayer 11 is exposed. That is, a patterned silicon carbide film 20 is formed on the underlayer 11. Thus, some regions of the underlayer 11 are shielded by the silicon carbide film 20, and other regions thereof are exposed to the outside. Thereafter, for example, if an etching process is performed or a deposition process is performed, an exposed region of the underlayer 11 is etched or a thin film is deposited. However, in the underlayer 11, a region shielded by the silicon carbide film 20 is not etched or a thin film is not deposited. That is, the silicon carbide film 20 serves as a mask which shields a portion of the underlayer 11 such that the underlayer 11 is selectively etched or deposited, and the silicon carbide film 20 is referred to as a hard mask.

In the above description, it has been described that the silicon carbide film 20 for a hard mask is formed on the underlayer 11 formed on one surface of the substrate 10. However, the present inventive concept is not limited thereto, and the silicon carbide film 20 for a hard mask may be directly formed on the substrate 10 on which the underlayer 11 is not formed.

In addition, the silicon carbide film 20 may be formed for an active layer which constitutes a power semiconductor device.

(a) to (c) of FIG. 3 are process diagrams conceptually illustrating a method for forming a silicon carbide film on a substrate by the method in accordance with the exemplary embodiment.

A method for forming the silicon carbide film 20 may include the steps of injecting a silicon (Si)-containing gas toward the substrate 10, thereby forming a silicon-containing film 21 on the substrate 10, forming first hydrogen plasma while injecting a carbon (C)-containing gas, thereby forming a silicon carbide film 22, forming second hydrogen plasma, thereby crystallizing the silicon carbide film 22 to form a crystalline silicon carbide film 20.

Here, the silicon (Si)-containing gas may be a ‘source gas,’ and the carbon (C)-containing gas may be a ‘reactant gas.’

Hereinafter, for the convenience of explanation, the step of forming the first hydrogen plasma while injecting the carbon-containing gas will be described as a ‘carbon-containing gas injecting step.’

In forming the silicon carbide film 20, the ‘silicon-containing gas injecting step—carbon-containing gas injecting step—hydrogen plasma formation step’ may be set as a single silicon carbide film formation cycle CY. That is, the method for forming the silicon carbide film 20 may include the silicon carbide film formation cycle CY, and the silicon carbide film formation cycle CY may include the silicon-containing gas injecting step, the carbon-containing gas injecting step, and the hydrogen plasma formation step.

In addition, the method for forming the silicon carbide film 20 may include a purge step. In addition, the method for forming the silicon carbide film 20 may further include at least one of a purge step (primary purge step) performed between the silicon-containing gas injecting step and the carbon-containing gas injecting step, and a purge step (secondary purge step) performed after the hydrogen plasma formation step. Here, the purge means supplying a purge gas into a chamber in which the substrate 10 is loaded, and exhausting the purge gas through an exhaust unit.

A turbomolecular pump (TMP) 100-1 may be connected between the exhaust unit and the chamber. In addition, a power pump may quickly reduce the pressure inside the chamber, quickly exhaust impurities and the like there inside, and enable a high-vacuum process. The turbo molecular pump 100-1 may be used to adjust the pressure to a high vacuum pressure of approximately 10 mTorr to approximately 50 mTorr.

If the method for forming the silicon carbide film 20 includes the purge step, the ‘silicon-containing gas injecting step—primary purge step—carbon-containing gas injecting step—hydrogen plasma formation step—secondary purge step’ may be set as a single silicon carbide film formation cycle CY. That is, the method for forming the silicon carbide film includes the silicon carbide film formation cycle CY, and the silicon carbide film formation cycle CY may include the silicon-containing gas injecting step, the primary purge step, the carbon-containing gas injecting step, the hydrogen plasma formation step, and the secondary purge step. In this case, in the silicon carbide film formation cycle CY, at least one of the primary purge step and the secondary purge step may be omitted.

In addition, the silicon carbide film formation cycle CY as described above may be performed n times (n: 1, 2, 3, . . . ). That is, the forming of the silicon carbide film 20 may include one time (n=1) or two or more times (n≥2) of the silicon carbide film formation cycle CY. Here, two or more times may mean a plurality of times.

In another embodiment, a method for forming the silicon carbide film 20 may include a pumping step of pumping the inside of a chamber in which a substrate is loaded, thereby controlling the pressure. If the method for forming the silicon carbide film 20 includes the pumping step, the ‘silicon-containing gas injecting step—primary pumping step—carbon-containing gas injecting step—hydrogen plasma formation step—secondary pumping step’ may be set as a single silicon carbide film formation cycle CY. That is, the method for forming the silicon carbide film includes the silicon carbide film formation cycle CY, and the silicon carbide film formation cycle CY may include the silicon-containing gas injecting step, the primary pumping step, the carbon-containing gas injecting step, the hydrogen plasma formation step, and the secondary pumping step. At this time, in the silicon carbide film formation cycle CY, at least one of the primary pumping step and the secondary pumping step may be omitted.

Here, the primary pumping step and the secondary pumping step may be a step of lowering the pressure inside the chamber by operating a pump, for example, a power pump, without injecting a purge gas into the chamber.

In addition, the silicon carbide film formation cycle CY as described above may be performed n times (n: 1, 2, 3, . . . ). That is, the forming of the silicon carbide film 20 may include one time (n=1) or two or more times (n≥2) of the silicon carbide film formation cycle CY. Here, two or more times may mean a plurality of times.

If the silicon carbide film formation cycle CY includes the pumping step as described above, there may be an advantage in that a gas remaining inside the chamber 100 and inside an exhaust unit for injecting a gas into the chamber may be quickly exhausted to the outside of the chamber.

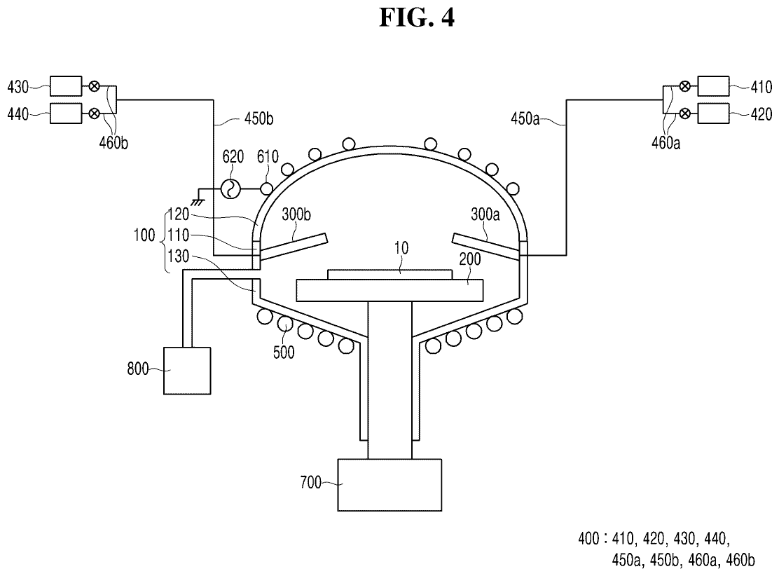

FIG. 4 is a view schematically showing a first substrate processing apparatus for forming silicon carbide films in accordance with exemplary embodiments.

Hereinafter, the first substrate processing apparatus illustrated in FIG. 4 will be described.

Referring to FIG. 4, the substrate processing apparatus may include a chamber 100, a support 200 installed inside the chamber 100 to support a substrate 10, first and second gas injection parts 300a and 300b installed inside the chamber 100 so as to each face the support 200, a gas supply unit 400 for providing a processing gas to the first and second gas injection parts 300a and 300b, an antenna 610 having a coil for inducing an electric field inside the chamber 100 to generate plasma, and a power supply unit 620 connected to the antenna 610.

In addition, the substrate processing apparatus may include a heating unit 500 installed to oppose the support 200, a driving unit 700 for lifting/lowing or rotating the support 200, and an exhaust unit 800 for exhausting gases and impurities inside the chamber 100.

In addition, the substrate processing apparatus may include a pump installed between the exhaust unit 800 and the chamber 100, and the pump may be connected to, for example, a turbomolecular pump 100-2. When the turbomolecular pump (TMP) 100-2 is operated, the pressure inside the chamber may be quickly lowered, and impurities thereinside may be quickly removed. As a result, it is possible to prevent the silicon carbide film from containing impurities.

The chamber 100 may be in the shape of a barrel having an internal space, and may be, for example, in the shape of a dome as illustrated in FIG. 4. More specifically, the chamber 100 may include a chamber body 110, an upper body 120 installed in an upper portion of the chamber body 110, and a lower body 130 installed in a lower portion of the chamber body 110. The chamber body 110 may be in the shape of a barrel having an upper portion and a lower portion that are open, and the upper body 120 is installed to cover the upper opening of the chamber body 110, and the lower body 130 may be installed to cover the lower opening of the chamber body 110. In addition, the upper body 120 may be in the shape of a dome having an inclined surface that increases in height toward the center of a width direction thereof. In addition, the lower body 130 may be in the shape of a dome having an inclined surface that decreases in height toward the center of a width direction thereof. The chamber 100, i.e., each of the chamber body 110, the upper body 120, and the lower body 130, may be made of a transparent material that allows light to pass therethrough, e.g., quartz.

The gas supply unit 400 may include a source gas supply unit 410 for supplying a silicon (Si)-containing gas (source gas), a reactant gas supply unit 420 for supplying a carbon-containing gas (reactant gas), a hydrogen-containing gas supply unit 430 for supplying a hydrogen-containing gas, and a discharge gas supply unit 440 for supplying a gas for discharge. In addition, the gas supply unit 400 may further include a purge gas supply unit (not shown) for supplying a purge gas.

In addition, the gas supply unit 400 may include a first transfer pipe 450a for connecting the source gas supply unit 410, the carbon-containing gas supply unit 420, and the first gas injection part 300a, and a second transfer pipe 450b for connecting the hydrogen-containing gas supply unit 430, the discharge gas supply unit 440, and the second gas injection part 300b.

In addition, the gas supply unit 400 may include a plurality of first connection pipes 460a for connecting the source gas supply unit 410, the reactant gas supply unit 420, and the first transfer pipe 450a, valves respectively installed in the plurality of first connection pipes 460a, a plurality of second connection pipes 460b for connecting the hydrogen-containing gas supply unit 430, the discharge gas supply unit 440, and the second transfer pipe 450b, and valves respectively installed in the plurality of second connection pipes 460b.

Then, the silicon carbide film 20 may be formed on the substrate 10 by using the substrate processing apparatus as described above.

Hereinafter, referring to (a) to (c) of FIG. 3, and FIG. 4, the method for forming the silicon carbide film 20 will be described in more detail.

First, the substrate 10 is loaded inside the chamber 100, and the substrate 10 is seated on the support 200. Then, the chamber 100 is heated using the heating unit 500. At this time, the temperature inside the chamber 100 is raised to approximately 300 °C to approximately 600 °C (approximately 300 °C or higher to approximately 600 °C or lower) by heating. The temperature inside the chamber 100 is maintained at approximately 300 °C to approximately 600 °C during a process.

If the temperature inside the chamber 100 is raised to approximately 300 °C to approximately 600 °C by heating, a silicon (Si)-containing gas (source gas) is injected toward the substrate 10. That is, a silicon (Si)-containing gas accommodated in the source gas supply unit 410 is supplied to the first gas injection part 300a through the first connection pipe 460a and the first transfer pipe 450a. Thus, the silicon-containing gas is injected from the first gas injection part 300a. That is, the silicon-containing gas is injected into the chamber 100 in which the substrate 10 is loaded. Here, the silicon-containing gas may be, for example, a SiH₂Cl₂(dichlorosilane) (DCS) gas. Of course, the silicon-containing gas is not limited to the above-described material, and various silicon-containing gases may be used.

If the silicon-containing gas is injected toward the substrate 10, components included in the silicon-containing gas are deposited or adsorbed on one surface of the substrate 10. Thus, as shown in (a) of FIG. 3, a film containing silicon (Si) (hereinafter, a silicon-containing film 21) is deposited on the substrate 10. More specifically, if the SiH₂Cl₂ gas is used as the silicon-containing gas, a SiH₂Cl₂ film, which is a film containing silicon (Si) and chlorine (Cl), may be formed on the substrate 10.

After the injecting of the silicon-containing gas is completed, a purge gas is injected into the chamber 100 and the exhaust unit 800 is operated to purge the inside of the chamber 100 in which the substrate 10 is loaded (primary purge). That is, the exhaust unit 800 is operated while injecting a purge gas, for example, an argon (Ar) gas, into the chamber 100 to purge the inside of the chamber 100. Here, the exhaust unit 800 may be a means including a pipe connected to the chamber 100 and a pump connected to the pipe.

After the primary purge is completed, a carbon-containing gas is injected toward the silicon-containing film 21 to generate first hydrogen plasma. That is, a carbon-containing gas accommodated in the reactant gas supply unit 420 is supplied to the first gas injection part 300a through the first connection pipe 460a and the first transfer pipe 450a. Thus, the carbon-containing gas is injected from the first gas injection part 300a. That is, the carbon (C)-containing gas is injected into the chamber 100 in which the substrate 10 is loaded. In addition, a hydrogen-containing gas accommodated in the hydrogen-containing gas supply unit 430 is supplied to the second gas injection part 300b through the second connection pipe 460b and the second transfer pipe 450b. Thus, the hydrogen-containing gas is injected from the second gas injection part 300b. That is, the hydrogen (H)-containing gas is injected into the chamber 100 in which the substrate 10 is loaded. Here, the hydrogen-containing gas may be a ‘hydrogen gas.’ As described above, while the carbon-containing gas and the hydrogen-containing gas are injected into the chamber 100, the gases injected into the chamber 100 are discharged to form the first hydrogen plasma. To this end, power or electric power is supplied to the antenna 610 by using the power supply unit 620. In this case, the power applied to the antenna 610 may be radio frequency (RF) power. In addition, the RF power applied to the antenna 610 may be approximately 800 Watts to approximately 900 Watts (hereinafter, approximately 800 W to approximately 900 W), or may be approximately 2.66 W/cm² to approximately 3 W/cm² per unit area of the substrate. In addition, the time for forming the first hydrogen plasma while injecting the carbon-containing gas may be approximately 1 second to approximately 3 seconds. That is, the first hydrogen plasma may be formed while injecting the carbon-containing gas for approximately 1 second to approximately 3 seconds. Here, since the antenna 610 is connected to the chamber 100, the application of the RF power to the antenna 610 may mean that the RF power is applied to the chamber 100.

It is preferable to further injection a discharge gas into the chamber 100 while injecting the carbon-containing gas and the hydrogen-containing gas. To this end, a discharge gas accommodated in the discharge gas supply unit 440 is supplied to the second gas injection part 300b through the second connection pipe 460b and the second transfer pipe 450b. Thus, the discharge gas is injected from the second gas injection part 300b. That is, the discharge gas is injected into the chamber 100. Here, the discharge gas may include an argon (Ar) gas.

As described above, since the hydrogen-containing gas is supplied into the chamber 100, and the hydrogen-containing gas is discharged inside the chamber 100, thereby generating the first hydrogen plasma, the first hydrogen plasma is direct plasma. That is, the first hydrogen plasma is not remote plasma in which plasma generated from the outside of the chamber 100 is supplied to the inside of the chamber 100, but is direct plasma in which plasma is generated inside the chamber 100.

When the carbon-containing gas is injected into the chamber 100, carbon (C) may be adsorbed or deposited on the silicon-containing film 21. Thus, the silicon carbide film 22 containing silicon (Si) and carbon (C) and being amorphous may be formed. When the carbon-containing gas is injected into the chamber 100, the hydrogen-containing gas is injected as described above, thereby forming the first hydrogen plasma. That is, the first hydrogen plasma is formed while the carbon-containing gas is injected. The first hydrogen plasma serves to prevent silicon (Si) from being separated from the silicon-containing film 21. That is, by forming the first hydrogen plasma, it is possible to suppress or prevent silicon (Si) from being separated from the silicon-containing film 21.

Meanwhile, in the related art, in order to prevent silicon from being separated from the silicon-containing film 21, the inside of the chamber 100 is heated to a high temperature of approximately 1000 °C or higher. However, if the silicon carbide film is formed and crystallized at a high temperature of approximately 1000 °C or higher, a large number of defects are generated in the silicon carbide film 20. Accordingly, when the crystallized silicon carbide film 20 is used as a conductive film, there is a problem of the generation of a leakage current due to the silicon carbide film.

On the other hand, in the exemplary embodiment, since the first hydrogen plasma is formed while the carbon-containing gas is injected, it is possible to suppress or prevent silicon (Si) from being separated from the silicon-containing film 21. That is, even in the state in which the temperature inside the chamber 100 is controlled to a low temperature of approximately 300 °C to approximately 600 °C instead of a high temperature of approximately 1000 °C or higher, it is possible to suppress or prevent silicon (Si) from being separated from the silicon-containing film 21. In other words, by forming the first hydrogen plasma when the carbon-containing gas is injected, it is possible to form the amorphous silicon carbide film 22 even at a low temperature of approximately 300 °C to approximately 600 °C. Thus, it is possible to form the amorphous silicon carbide film 22 with a few or no defects.

In addition, the silicon-containing gas may contain chlorine (Cl) in addition to silicon, and the chlorine (Cl) may degrade properties of the silicon carbide film. For example, electrical resistivity of the silicon carbide film may increase due to the chlorine (Cl). However, in the exemplary embodiment, by forming the first hydrogen plasma while injecting the carbon-containing gas, it is possible to form the silicon carbide film 22 having a reduced content of chlorine (Cl). That is, when the first hydrogen plasma is formed, hydrogen (H) ions and chlorine (Cl) contained in the silicon-containing film 21 react with each other, thereby generating a hydrochloric acid (HCl) gas. Then, the hydrochloric acid (HCl) gas is exhausted to the outside through the exhaust unit 800. Thus, it is possible to form a silicon carbide film not containing chlorine (Cl) or having a small content of chlorine (Cl), and as a result, it is possible to reduce the electrical resistivity of the silicon carbide film.

In forming the first hydrogen plasma, RF power is applied to the antenna 610. In this case, the RF power applied to the antenna 610 is approximately 800 W to approximately 900 W, or approximately 2.66 W/cm² to approximately 3 W/cm² per unit area with respect to the substrate 10.

Meanwhile, if the RF power applied to the antenna 610 is less than approximately 800 W, or the RF power per unit area of the substrate 10 is less than approximately 2.66 W/cm², a large amount of silicon (Si) may be separated from the silicon-containing film. Therefore, the RF power applied to the antenna 610 should be approximately 800 W or higher, or the RF power per unit area of the substrate 10 should be approximately 2.66 W/cm² or higher.

In addition, the RF power applied to the antenna 610 is not particularly limited within the range of 800 W or higher. In addition, the RF power per unit area of the substrate is not particularly limited within the range of 2.66 W/cm² or higher. However, the maximum value of applicable RF power may vary depending on a substrate processing apparatus. For example, the substrate processing apparatus used in the exemplary embodiment may have a maximum value of RF power of approximately 900 W applicable to the antenna 610, and a maximum value of approximately 3 W/cm² thereof based on the unit area of the substrate. Therefore, the first hydrogen plasma is formed by applying approximately 800 W to approximately 900 W of RF power to the antenna 610, or approximately 2.66 W/cm² to approximately 3 W/cm² of RF power per unit area with respect to the substrate 10 thereto.

If the first hydrogen plasma is formed by applying approximately 800 W to approximately 900 W of RF power to the antenna 610, or applying approximately 2.66 W/cm² to approximately 3 W/cm² of RF power per unit area with respect to the substrate 10 thereto, it is possible to suppress or prevent silicon (Si) from being separated from the silicon-containing film 21. That is, even if the temperature inside the chamber 100 is controlled to a low temperature of approximately 300 °C to approximately 600 °C, due to the first hydrogen plasma, it is possible to suppress or prevent silicon (Si) from being separated from the silicon-containing film 21. Therefore, it is possible to form the amorphous silicon carbide film 22 with a few or no defects.

After the forming of the first hydrogen plasma while injecting the carbon-containing gas is completed, a process of forming the second hydrogen plasma inside the chamber 100 is performed. To this end, RF power is applied to the antenna 610 by using the power supply unit 620 while injecting a hydrogen-containing gas into the chamber 100. More specifically, the hydrogen-containing gas accommodated in the hydrogen gas supply unit 430 is supplied to the second gas injection part 300b through the second connection pipe 460b and the second transfer pipe 450b. In addition, the discharge gas, e.g., an argon (Ar) gas, accommodated in the discharge gas supply unit 440 may be supplied to the second gas injection part 300b. Thus, the hydrogen-containing gas and the discharge gas are injected from the second gas injection part 300b. That is, the hydrogen-containing gas and the discharge gas are injected into the chamber 100. Then, RF power is applied to the antenna 610 by using the power supply unit 620. The RF power applied in the second hydrogen plasma formation step may be the same as the RF power applied in the first hydrogen plasma formation step. That is, the RF power applied to the antenna 610 in the second hydrogen plasma formation step may be approximately 800 W to approximately 900 W, or may be approximately 2.66 W/cm² to approximately 3 W/cm² per unit area of the substrate. In addition, the time for forming the second hydrogen plasma may be longer than the time for forming the first hydrogen plasma. That is, the time for forming the first hydrogen plasma while injecting the carbon-containing gas may be approximately 1 second to approximately 3 seconds, and the time for forming the second hydrogen plasma may be approximately seconds to approximately 20 seconds.

Once the second hydrogen plasma is formed, the amorphous silicon carbide film 22 may be crystallized. That is, the second hydrogen plasma crystallizes the silicon carbide film 22, and as a result, the crystallized silicon carbide film 20 is formed.

Meanwhile, in the related art, in order to crystallize the amorphous silicon carbide film 21, the temperature inside the chamber 100 was raised to a high temperature of 1000 °C or higher by heating. However, if the amorphous silicon carbide film is crystallized at a high temperature of approximately 1000 °C or higher, a large number of defects are generated in the silicon carbide film 20. Accordingly, when the crystallized silicon carbide film 20 is used as a conductive film, there is a problem of the generation of a leakage current due to the silicon carbide film 20.

On the other hand, in the exemplary embodiment, by forming the second hydrogen plasma after forming the amorphous silicon carbide film 22, it is possible to crystallize the amorphous silicon carbide film 22. That is, it is possible to crystallize the amorphous silicon carbide film 22 by using the second hydrogen plasma without having to raise the temperature inside the chamber 100 to a high temperature of approximately 1000 °C or higher by heating. In other words, by forming the second hydrogen plasma, it is possible to crystallize the amorphous silicon carbide film 22 even in the state in which the temperature inside the chamber 100 is controlled to a low temperature of approximately 300 °C to approximately 600 °C. Thus, it is possible to form the crystalline silicon carbide film 20 with a few or no defects.

In forming the second hydrogen plasma, RF power is applied to the antenna 610. In this case, the RF power applied to the antenna 610 is approximately 800 watts (W) to approximately 900 watts (W), or approximately 2.66 W/cm² to approximately 3 W/cm² per unit area with respect to the substrate 10.

Meanwhile, if the RF power applied to the antenna 610 is less than approximately 800 W, or the RF power per unit area of the substrate 10 is less than approximately 2.66 W/cm², the amorphous silicon carbide film 22 may not be crystallized or may have a decreased crystallization rate. Therefore, the RF power applied to the antenna 610 should be approximately 800 W or higher, or the RF power per unit area of the substrate 10 should be approximately 2.66 W/cm² or higher.

The maximum value of applicable RF power may vary depending on a substrate processing apparatus. For example, the substrate processing apparatus used in the exemplary embodiment may have a maximum value of RF power of approximately 900 W applicable to the antenna 610, and a maximum value of approximately 3 W/cm² thereof based on the unit area of the substrate 10. Therefore, the second hydrogen plasma is formed by applying approximately 800 W to approximately 900 W of RF power to the antenna 610, or approximately 2.66 W/cm² to approximately 3 W/cm² of RF power per unit area with respect to the substrate 10 thereto.

As described above, if the second hydrogen plasma is formed by applying approximately 800 W to approximately 900 W of RF power to the antenna 610, or applying approximately 2.66 W/cm² to approximately 3 W/cm² of RF power per unit area based on the substrate 10 thereto, it is possible to crystallize the amorphous silicon carbide film 22. That is, even if the temperature inside the chamber 100 is controlled to a low temperature of approximately 300 °C to approximately 600 °C, the amorphous silicon carbide film 22 may be crystallized by the second hydrogen plasma. Therefore, it is possible to form the crystalline silicon carbide film 20 with a few or no defects.

Thereafter, a purge gas is supplied into the chamber 100 and the exhaust unit 800 is operated to purge the chamber 100 (secondary purge).

A process including the silicon-containing gas injecting step, the primary purge step, the carbon-containing gas injecting step (first hydrogen plasma formation step), the second hydrogen plasma formation step, and the secondary purge step, which are described above, may be set as a single silicon carbide film formation cycle CY. That is, the cycle CY for forming the silicon carbide film may include the ‘silicon-containing gas injecting step—primary purge step—carbon-containing gas injecting step (first hydrogen plasma formation step)—second hydrogen plasma formation step—secondary purge step.’ Then, the silicon carbide film formation cycle CY may be performed one time or one or more times consecutively to form the silicon carbide film 20 having a target thickness.

In the above description, it has been described that the carbon-containing gas and the hydrogen-containing gas are separately supplied and injected in the carbon-containing gas injecting step. However, a gas containing both carbon and hydrogen may be supplied into the chamber 100. To this end, the substrate processing apparatus may include a mixed gas storage unit for supplying a mixed gas containing carbon and hydrogen, and the mixed gas storage unit may be connected to at least one of the first gas injection part 300a and the second gas injection part 300b. Thus, the mixed gas in the mixed gas storage unit may be injected into the chamber 100 through at least one of the first and second gas injection parts 300a and 300b. In the case, the mixed gas containing carbon and hydrogen may be, for example, a methane (CH₄) gas. Of course, the mixed gas containing carbon and hydrogen is not limited to the above-described example, and a variety of gases containing carbon and hydrogen may be applied. (a) to (d) of FIG. 5 (d) are process diagrams conceptually illustrating a method for forming a silicon carbide film on a substrate by a method in accordance with another exemplary embodiment.

Compared to the exemplary embodiment, a silicon carbide film formation cycle CY in accordance with another exemplary embodiment may further include a hydrogen plasma formation step (hereinafter, a third plasma formation step) between the silicon-containing gas injecting step and the carbon-containing gas injecting step. More specifically, the silicon carbide film formation cycle CY in accordance with another exemplary embodiment may further include a step of forming third plasma between the silicon-containing gas injecting step and the primary purge step. That is, the silicon carbide film formation cycle CY in accordance with another exemplary embodiment may include the ‘silicon-containing gas injecting step—third plasma formation step—primary purge step—carbon-containing gas injecting step (first hydrogen plasma formation step)—second hydrogen plasma formation step—secondary purge step.’ In this case, in the silicon carbide film formation cycle CY, at least one of the primary purge step and the secondary purge step may be omitted. In addition, the silicon carbide film formation cycle CY as described above may be performed n times (n: 1, 2, 3, . . . ). That is, the forming of the silicon carbide film may include one time (n=1) or two or more times (n≥2) of the silicon carbide film formation cycle CY. Here, two or more times may mean a plurality of times.

Meanwhile, the silicon-containing gas may contain impurities in addition to silicon (Si), and as a result, the impurities may be included in the silicon-containing film 21. In addition, due to the impurities included in the silicon-containing film 21, the quality of the silicon carbide film 20 may be degraded.

Therefore, in the exemplary embodiment, the silicon-containing gas is injected, thereby forming the silicon-containing film 21 on the substrate 10, and then the third hydrogen plasma is formed to remove the impurities from the silicon-containing film 21. If hydrogen plasma (the third hydrogen plasma) is formed after the silicon-containing film 21 is formed, the silicon-containing film 21 is exposed to the hydrogen plasma, and at this time, the silicon-containing film 21 may react with the hydrogen plasma to separate or remove the impurities from the silicon-containing film 21. Therefore, the quality of the silicon carbide film 20 may be improved.

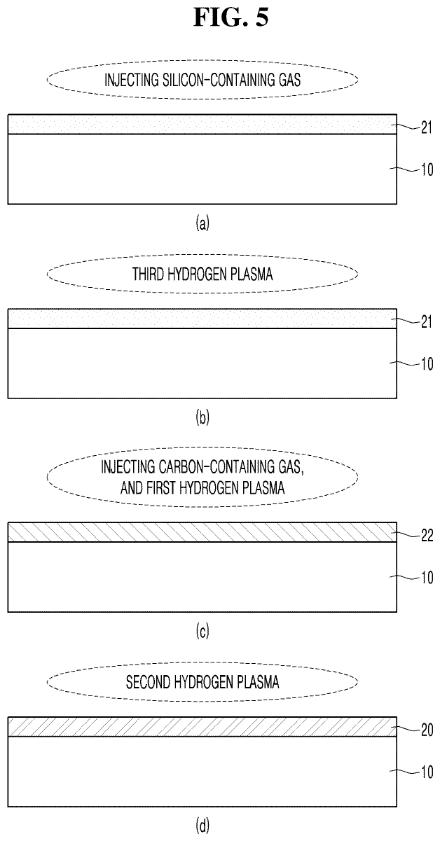

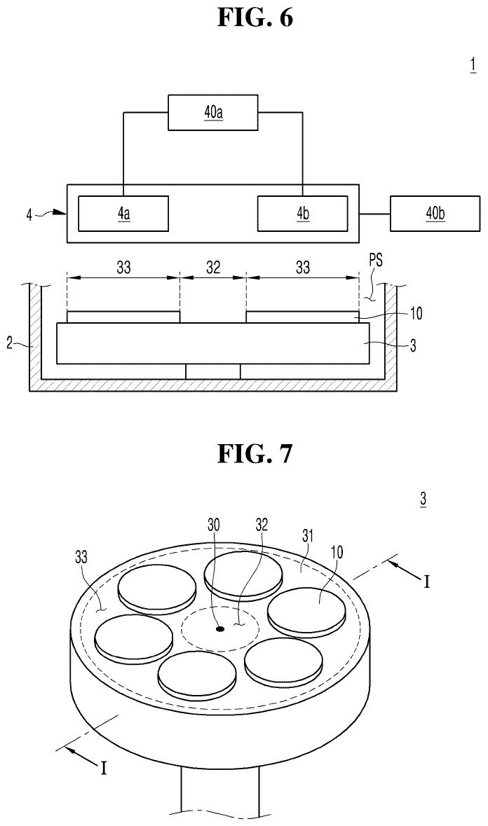

A substrate processing apparatus for forming the silicon carbide film 20 is not limited to the first substrate processing apparatus illustrated in FIG. 4. In forming the silicon carbide film 20, the silicon carbide film 20 may be formed using substrate processing apparatuses of other exemplary embodiments illustrated in FIG. 6 to FIG. 13.

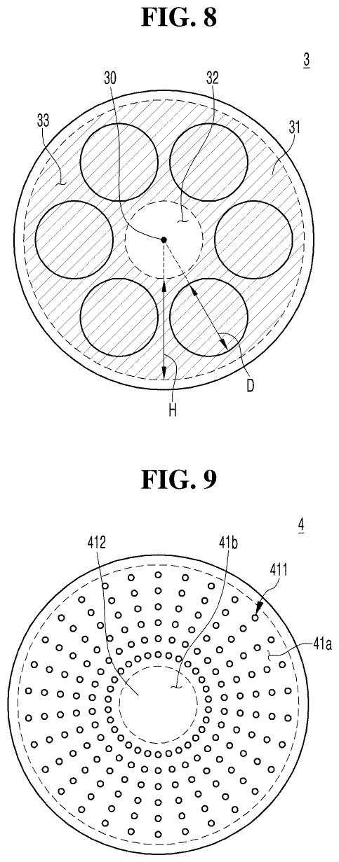

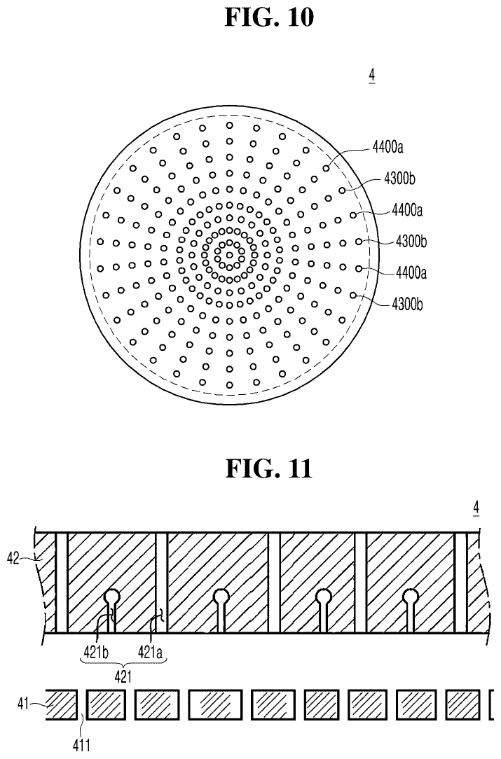

FIG. 6 is a view schematically showing a substrate processing apparatus of another embodiment capable of forming a silicon carbide film in accordance with an exemplary embodiment. FIG. 7 is a schematic perspective view of a substrate support part in the substrate processing apparatus of another exemplary embodiment. FIG. 8 is a plan view of a substrate support part in the substrate processing apparatus of another exemplary embodiment. FIG. 9 is a schematic bottom view of an injection part in the substrate processing apparatus of another exemplary embodiment. FIG. 10 is a schematic bottom view of an injection part in the substrate processing apparatus of another exemplary embodiment. FIG. 11 is a schematic side-sectional view of a modified example of an injection part in a substrate processing apparatus of another exemplary embodiment. FIG. 13 is a schematic side-sectional view of a modified example of an injection part in a substrate processing apparatus of another exemplary embodiment.

Hereinafter, referring to FIG. 6 to FIG. 13, the substrate processing apparatuses of other exemplary embodiments, the apparatuses capable of forming a silicon carbide film will be described. In this case, the reference numerals illustrated in FIG. 6 to FIG. 13 are reference numerals separately shown from FIG. 1 to FIG. 5 described above.

Referring to FIG. 6, a substrate processing apparatus 1 of another exemplary embodiment performs a processing process on a substrate 10. The substrate processing apparatus 1 of another exemplary embodiment may perform a deposition process of depositing a thin film on the substrate 10.

The substrate processing apparatus 1 of another exemplary embodiment may include a chamber 2, a substrate support part 3, and an injection part 4. In addition, although not illustrated, a heater (not shown) capable of controlling the temperature inside the chamber 2 may be installed in at least one of the substrate support part 3 and the chamber 2. In addition, a turbomolecular pump (TMP) 100-1 may be installed in an exhaust unit (not shown).

Referring to FIG. 6, the chamber 2 may provide a processing space PS. The processing process may be performed on the substrate 10 in the processing space PS. The processing space PS may be disposed inside the chamber 2. The chamber 2 may be coupled to an exhaust unit (not shown) for exhausting a gas from the processing space PS, and may be additionally coupled to the turbomolecular pump 100-1. The substrate support part 3 and the injection part 4 may be disposed inside the chamber 2.

Referring to FIG. 6 to FIG. 9, the substrate support part 3 supports the substrate 10. The substrate support part 3 may support one substrate 10, and in addition, the substrate support part 3 may support a plurality of substrates 10. For example, the substrate support part 3 may support one substrate to six substrates 10. Accordingly, the substrate processing apparatus 1 of another exemplary embodiment may perform a processing process on one substrate 10 or the plurality of substrates 10 at a time. The substrate support part 3 may be coupled to the chamber 2. The substrate support part 3 may be disposed inside the chamber 2.

The substrate support part 3 may include a support surface 31. The support surface 31 may be a surface of the substrate support part 3 disposed to face the injection part 4. If the substrate support part 3 is disposed on a lower side of the injection part 4, the support surface 31 may correspond to an upper surface of the substrate support part 3. The substrates 10 may be supported by the support surface 31.

The substrate support part 3 may support the substrates 10 in an outer region 33 disposed on an outer side with respect to a central region 32. The outer region 33 may be disposed to surround the central region 32. Accordingly, the central region 32 may be disposed on an inner side of the outer region 33. If the central region 32 is formed in the shape of a circle, the outer region 33 may be formed in the shape of a circular ring surrounding the central region 32. The substrates 10 may be disposed spaced apart from each other along the outer region 33. In this case, the substrates 10 may be supported by the support surface 31 so as to be spaced apart from each other at the same angle with respect to a central axis 30 of the substrate support part 3 in the outer region 33. If the substrate support part 3 is rotated while the above-described processing process is performed, the substrate support part 3 may be rotated with respect to the central axis 30. If the support surface 31 is formed in the shape of a circle, the central axis 30 may correspond to the center of the support surface 31. Meanwhile, since the substrates 10 are supported by the support surface 31 in the outer region 33, the substrates 10 are not positioned in the central region 32. If the central region 32 is formed in the shape of a circle, the diameter of the central region 32 may be implemented to be larger than a diameter D (shown in FIG. 8) of the substrate 10 and to be smaller than twice the diameter D of the substrate 10. The diameter of the central region 32 may also be implemented to be smaller than the diameter D of the substrate 10.

A gas storage unit 40a stores a gas and temporarily supplies the gas to the injection part 4. In addition, the gas storage unit 40a may be a pile-up tank. A process gas may be temporarily stored in the gas storage unit 40a, and the temporarily stored process gas may be instantaneously injected into the processing space PS through the injection part 4. That is, the gas storage unit 40a stores a gas for forming the silicon carbide film 20 in accordance with the exemplary embodiments and instantaneously increases a gas injecting flow rate to supply the gas to the injection part 4. There may be separate gas storage units for a source gas and a reactant gas, respectively.

Although one gas storage unit 40a is illustrated in FIG. 6, a plurality of gas storage units may be provided. That is, the substrate processing apparatus of another exemplary embodiment may include a gas storage unit in which a silicon-containing gas (source gas) is stored, a gas storage unit in which a carbon-containing gas (reactant gas) is stored, a gas storage unit in which a hydrogen-containing gas is stored, and a gas storage unit in which a discharge gas is stored. A gas constant supply part (not shown) capable of supplying a gas at all times may be present at an upper end of the gas storage unit. In addition, the substrate processing apparatus of another exemplary embodiment may further include a gas storage unit in which a mixed gas containing both carbon (C) and hydrogen (H) is stored, and a gas storage unit in which a purge gas is stored.

Referring to FIG. 6 to FIG. 13, the injection part 4 injects a gas toward the substrate support part 3. The injection part 4 may be installed inside the chamber 2 to inject a gas into the chamber 2. The injection part 4 may inject a gas toward the support surface 31. The injection part 4 may be connected to the gas storage unit 40a. In this case, the injection part 4 may inject a gas supplied from the gas storage unit 40a toward the substrate support part 3. That is, the injection part 4 injects the silicon-containing gas, the carbon-containing gas, the hydrogen-containing gas, and the discharge gas provided from the respective gas storage units 40a toward the substrate support part 3. In addition, the injection part 4 may inject the mixed gas containing carbon and hydrogen, and the purge gas toward the substrate support part 3.

The injection part 4 may be disposed inside the chamber 2. The injection part 4 may be disposed to oppose the substrate support part 3. The injection part 4 may be disposed on an upper side of the substrate support part 3. The processing space PS may be disposed between the injection part 4 and the substrate support part 3. The injection part 4 may be coupled to a lid (not shown). The lid may be coupled to the chamber 2 so as to cover an upper portion of the chamber 2.

The injection part 4 may inject a gas only toward the outer region 33. In this case, the injection part 4 is implemented not to inject a gas toward the central region 32. That is, the injection part 4 may inject a gas toward the outer region 33 except for the central region 32. Accordingly, the substrate processing apparatus 1 of another exemplary embodiment is implemented not to inject a gas toward a portion of the support surface 31 (i.e., the central region 32) in which the substrate 10 is not present, but to inject a gas only toward a portion of the support surface 31 (i.e., the outer region 33) in which the substrates 10 are present.

Therefore, the substrate processing apparatus 1 of another exemplary embodiment may reduce the flow rate of a gas flowing into the central region 32 in which the substrate 10 is not present, thereby being wasted without being involved in the above-described processing process. Accordingly, the substrate processing apparatus 1 of another exemplary embodiment may reduce operating costs by reducing the flow rate of the wasted gas. In addition, if the substrate processing apparatus 1 of another exemplary embodiment is used to form the silicon carbide film 20, manufacturing costs required to manufacture the silicon carbide film 20 may be lowered.

In addition, since the substrate processing apparatus 1 of another exemplary embodiment is implemented such that a gas is injected intensively toward the outer region 33 in which the substrates 10 are present, it is possible to increase the flow rate of a gas flowing into the outer region 33 in which the substrates 10 are present, thereby being involved in the above-described processing process. Therefore, the substrate processing apparatus 1 of another exemplary embodiment may improve the quality of the substrate 10 on which the above-described processing process is performed.

The injection part 4 may inject the same gas to the entire outer region 33. If the above-described processing process is performed using a plurality of gases, the injection part 4 may perform the above-described processing process by sequentially repeating injecting the same gas to the entire outer region 33. In this case, the injection part 4 may perform the above-described processing process in a time-divided deposition (TSD) manner in which a plurality of gases are injected in a time-divided manner. For example, if the above-described processing process is performed using a silicon-containing gas, a carbon-containing gas, and a hydrogen-containing gas, the injection part 4 may inject the silicon-containing gas to the entire outer region 33 and then inject the carbon-containing gas and the hydrogen-containing gas to the entire outer region 33 in the state in which the injecting of the silicon-containing gas is stopped. In addition, in the state in which the injecting of the carbon-containing gas is stopped, the hydrogen-containing gas may be injected to the entire outer region 33.

The injection part 4 may be connected to a power supply unit 40b. The power supply unit 40b may apply plasma power source to the injection part 4. For example, the plasma power source may be RF power. The plasma power source applied from the power supply unit 40b may be used to generate plasma inside the chamber 2. For example, plasma may be generated inside the injection part 4 connected to the power supply unit 40a, and the generated plasma may be injected to a lower side of the injection part 4. As described above, if the plasma is generated inside the injection part 4, the plasma may be generated only in a portion of the injection part 4 corresponding to the outer region 33.

As another example, the injection part 4 may be set as a first electrode, and the substrate support part 3 may be set as a second electrode to generate plasma between the injection part 4 and the substrate support part 4. That is, the injection part 4 may be used to inject the hydrogen-containing gas to a lower side, and the RF power may be applied to the injection part 4 to generate hydrogen plasma between the injection part 4 and the substrate support part 3 by using a potential difference between the injection part 4 and the substrate support part 3. In this case, the injection part 4 may further inject the discharge gas to the hydrogen (H)-containing gas. Here, a space between the injection part 4 and the substrate support part 4 may be the processing space PS of the chamber 2.

As described above, since plasma is generated inside the chamber 2, the plasma is direct plasma. That is, the above-described plasma is not remote plasma in which plasma generated from the outside of the chamber 2 is supplied to the inside of the chamber 2, but is direct plasma in which plasma is generated inside the chamber 2.

The substrate processing apparatus 1 of another exemplary embodiment uses the plasma to perform crystallization, film densification, impurity removal, or the like on a thin film formed on each of the substrates 10, and thus, may further improve the quality of the substrate 10 on which the process is performed. If plasma is generated in the processing space PS, the plasma may be formed only in a portion of the processing space PS corresponding to the outer region 33.

The injection part 4 may inject the silicon-containing gas only toward the outer region 33, and then may inject the carbon-containing gas and the hydrogen-containing gas only toward the outer region 33, or may inject a mixed gas containing carbon and hydrogen theretoward. In this case, the substrate processing apparatus 1 of another exemplary embodiment may be implemented to form a thin film on the substrate 10 in an atomic layer deposition (ALD) manner. In the case, a film (thin film) formed on a substrate by using the substrate processing apparatus 1 of another exemplary embodiment may be the crystalline silicon carbide film 20. The injection part 4 may inject a silicon-containing gas toward the front surface of a portion of the support surface 31 which belongs to the outer region 33, and then inject a carbon-containing gas and a hydrogen-containing gas theretoward.

Accordingly, the substrate processing apparatus 1 of another exemplary embodiment may be implemented such that a source material contained in the silicon-containing gas is adsorbed on all of the substrates 10 disposed in the outer region 33, and then a thin film is formed in all of the substrates 10 disposed in the outer region 33 by a reaction using the carbon-containing gas and the hydrogen-containing gas. Therefore, the substrate processing apparatus 1 of another exemplary embodiment may reduce the process time required until a processing process is performed on all of the substrates 10 disposed in the outer region 33, and thus, may increase productivity of the substrate 10 for which the processing process is completed. In addition, since the substrate processing apparatus 1 of another exemplary embodiment may reduce the deviation of process conditions between the substrates 10 disposed in the outer region 33, it is possible to improve the uniformity of quality between the substrates 10 on which the process is performed.

The injection part 4 may further inject a purge gas. To this end, the substrate processing apparatus 1 of another exemplary embodiment may further include a gas storage unit in which the purge gas is stored. In addition, the injection part 4 may sequentially inject the silicon-containing gas, the purge gas, the carbon-containing gas, the hydrogen-containing gas, and the purge gas only toward the outer region 33. The purge gas may purge the silicon-containing gas remaining in the processing space PS, or may purge the carbon-containing gas and the hydrogen-containing gas remaining in the processing space PS. The purge gas does not involve in the processing process, and for example, an inert gas such as argon (Ar) may be used. By using the purge gas, the substrate processing apparatus 1 of another exemplary embodiment may further improve the quality of the thin film formed on the substrate 10 in the atomic layer deposition (ALD) manner.

The injection part 4 may include a first gas flow path 4a, and a second gas flow path 4b.

The first gas flow path 4a is for injecting a first gas. One side of the first gas flow path 4a may be connected to the gas storage unit 40a through a pipe, a hose, a gas block, or the like. The other side of the first gas flow path 4a may communicate with the processing space PS. Accordingly, the first gas supplied from the gas storage unit 40a may flow along the first gas flow path 4a and then be injected into the processing space PS through the first gas flow path 4a. The first gas flow path 4a may function as a flow path through which the first gas flows and may also function as an injection port for injecting the first gas into the processing space PS.

The second gas flow path 4b is for injecting a second gas. The second gas and the first gas may be gases different from each other. For example, if the first gas is a silicon-containing gas, the second gas may be a carbon-containing gas. As another example, the first gas may be a hydrogen-containing gas, and the second gas may be a carbon-containing gas. One side of the second gas flow path 4b may be connected to the gas storage unit 40a through a pipe, a hose, a gas block, or the like. The other side of the second gas flow path 4b may communicate with the processing space PS. Accordingly, the second gas supplied from the gas storage unit 40a may flow along the second gas flow path 4b and then be injected into the processing space PS through the second gas flow path 4b. The second gas flow path 4b may function as a flow path through which the second gas flows and may also function as an injection port for injecting the second gas into the processing space PS.

The second gas flow path 4b and the first gas flow path 4a may be disposed to be spatially separated from each other. Accordingly, the second gas supplied from the gas storage unit 40a to the second gas flow path 4b may be injected into the processing space PS without passing through the first gas flow path 4a. The first gas supplied from the gas storage unit 40a to the first gas flow path 4a may be injected into the processing space PS without passing through the second gas flow path 4b. In this case, the second gas flow path 4b may inject the second gas only toward the outer region 33. The first gas flow path 4a may inject the first gas only toward the outer region 33.

The injection part 4 may include a second plate 41 and a plurality of third openings 411. A source gas, reactant gas or mixed gas injected from the above through the plurality of the third openings 411 may be injected to the substrate 10 through the third opening 411, and the gas transformed into plasma by the application of RF power may be injected to the substrate 10 through the third opening 411.

The second plate 41 may be disposed on an upper side of the substrate support part 3, and a first plate 42 may be disposed in an upper portion of the second plate 41. The second plate 41 may be disposed spaced apart upward from the substrate support part 3. The bottom surface of the second plate 41 facing the substrate support part 3 may be formed to have the same area as the support surface 31. The bottom surface of the second plate 41 may be formed to have a larger area than the support surface 31.

The third openings 411 may be formed in the second plate 41. The third openings 411 may allow a gas to pass therethrough. The gas may pass through the second plate 41 through the third openings 411 and be injected toward the substrate support part 3. The third openings 411 may be formed only in a first passage region 41a (shown in FIG. 10) corresponding to the outer region 33. Alternatively, a gas may be injected to both the outer region 33 and the central region 32. Accordingly, the injection part 4 may be implemented to inject a gas only toward the outer region 33 by using the third openings 411. The third openings 411 may be disposed spaced apart from each other in the first passage region 41a, and the third openings 411 may be disposed in a zigzag manner with respect to a gas injection hole of the first plate 42. The zigzag arrangement may mean that gas holes do not face each other, and are disposed at different positions.

On the first plate 42, a plurality of first openings 421a through which a source gas containing silicon is injected and a plurality of second openings 421b through which a reactant gas containing carbon is injected may be formed.

The first openings 421a may be formed by vertically passing through the first plate 42. The first openings 421a may belong to the first gas flow path 4a. Accordingly, the first openings 421a may allow a first gas to pass therethrough. The first openings 421a may be formed only in the first passage region 41a. The first gas may be a source gas.

The third openings 411 of the second plate 41 may be disposed in a zigzag manner so as not to face the first openings 421a and the second openings 421b of the first plate 42. The zigzag arrangement may mean that gas holes do not face each other, and are disposed at different positions. The source gas or the reactant gas injected from the first openings 421a and the second openings 421b of the first plate 42 may not directly pass through the third opening 411 of the second plate 41, but may hit an upper surface of the second plate 41 and then pass through the third opening 411. Plasma may be formed using a potential difference between the second plate 41 and the first plate 42. A RF power supply unit 40b may be connected either the second plate 41 or the first plate 42.

One side of each of the second openings 421b may be formed by passing through the inside of the first plate 42. The other side of each of the second openings 421b may be formed by passing through a side surface of the first plate 42, without passing through an upper surface of the first plate 42. The second openings 421b may be formed in a gundrill manner. The second openings 421b may belong to the second gas flow path 4b for injecting a reactant gas containing carbon. Accordingly, the second openings 421b may allow a second gas to pass therethrough. The first openings 431a and the second openings 421b may be formed only in the first passage region 41a. The second openings 411b and the first openings 411a may be disposed spaced apart from each other in the first passage region 41a. The first openings 431a and the second openings 411b may be disposed in the entire first passage region 41a to inject a gas toward all of the substrates 10 disposed in the outer region 33, thereby injecting the gas to the front surface. The first openings 411a may be disposed in the entire first passage region 41a to inject a gas toward all of the substrates 10 disposed in the outer region 33.

The second plate 41 and a first blocking member 412 may be included.

The second plate 41 may block the passage of a gas. The first blocking member 412 may be disposed in a first blocking region 41b (shown in FIG. 9) corresponding to the central region 32. Accordingly, the injection part 4 may be implemented to block the injecting of a gas toward the central region 32 by using the first blocking member 412 and to inject a gas only toward the outer region 33 by using the third openings 411. The third openings 411, the first openings 431a, and the second openings 411b may not be formed in the first blocking member 412. The first blocking region 41b and the central region 32 may be formed to have the same shape and the same size. The first blocking region 41b may be disposed on an inner side of the first passage region 41a. The first passage region 41a may be disposed on an outer side of the first blocking region 41b so as to surround the first blocking region 41b. If the first blocking region 41b is formed in the shape of a circle, the first passage region 41a may be formed in the shape of a circular ring, a donut, or a tube surrounding the first blocking region 41b.

Referring to FIG. 11, the injection part 4 may include the first plate 42, and a plurality of gas holes 421.

The first plate 42 may be disposed on an upper side of the second plate 41. The first plate 42 may be disposed spaced apart upward from the second plate 41. The bottom surface of the first plate 42 facing the second plate 41 may be formed flat. The bottom surface of the first plate 42 may be formed to have the same area as the support surface 31. The bottom surface of the first plate 42 may be formed to have a larger area than the support surface 31.

The gas holes 421 may be formed in the first plate 42. The gas holes 421 may allow a gas to pass therethrough. The gas may pass through the first plate 42 through the gas holes 421 and be injected toward the second plate 41. When viewed from above or below the third opening 411 of the second plate 41, the position of the gas hole 421 of the first plate 42 does not match the position of the third opening 411.

In another exemplary embodiment, the gas holes 421 may be formed only in a second passage region 42a (shown in FIG. 9) corresponding to the outer region 33. Accordingly, the injection part 4 may be implemented so as to inject a gas only toward the outer region 33 by using the gas holes 421 and the third openings 411. In this case, the gas may pass between the first plate 42 and the second plate 41. Accordingly, the gas may be injected only toward the outer region 33 by passing through the gas holes 421 and the third openings 411. The gas holes 421 may be disposed spaced apart from each other in the second passage region 42a. The second passage region 42a, the first passage region 41a, and the outer region 33 may be formed to have the same shape and the same size.

Plasma may be formed between the second plate 41 and the first plate 42. The second plate 41 may be set as a first electrode, and the first plate 42 may be set as a second electrode to allow RF power to be connected to the first electrode or the second electrode. That is, plasma may be formed in a space between the second plate 41 and the first plate 42 by using a potential difference therebetween.

When a first gas and a second gas are injected to the first plate 42, the first gas and the second gas may be injected toward a lower substrate through the third opening 411 of the second plate 41.

The third opening 411 or the gas hole 421 is formed in the center of the second plate 41 and the first plate 42 without a blocking region, so that a gas may be injected to the front surface of both the second plate 41 and the first plate 42. In addition, a chamber 2 may accommodate the first plate 42 including the first opening 421a and the second opening 421b, the second plate 41 electrically insulated from the first plate 42, spaced apart from the first plate 42, and having the plurality of third openings 411 alternately disposed with the first openings 421a and the second openings 421b, and a turbo molecular pump (TMP) 100-1. In addition, the chamber 2 including the turbomolecular pump (TMP) 100-1 may be controlled to a pressure of approximately 10 mTorr to approximately 50 mTorr at a pressure of high vacuum. The first opening 421a may be connected from the gas storage unit 40a, wherein the gas storage unit may be connected to the first opening 421a to temporarily inject one or one or more gases. The gas storage unit 40a may include a pile-up tank. The first gas flow path 4a may be connected to the pile-up tank to fill the tank with one or one or more gases, and the filled gas may be temporarily injected.

The first plate 42 may include a second blocking member (not shown) on an upper surface of the first blocking member 412 of the second plate 41.

The second blocking member (not shown) may block the passage of a gas. The second blocking member (not shown) may be disposed in a second blocking region (not shown) corresponding to the central region 32. In addition, since the first blocking member 412 and the second blocking member (not shown) may be connected to each other, a space between the second plate 41 and the first plate 42 may be blocked to reduce the waste of space. A material for blocking the space between the first blocking member 412 and the second blocking member (not shown) disposed in an upper portion of the first blocking member 412 may be a material different from that of the second plate 41 and the first plate 42, and may be, for example, a material such as Teflon, quartz, or the like. Due to the first blocking member 412, the injection part 4 may be implemented to block the injecting of a gas toward the central region 32 by using the second blocking member (not shown) and the first blocking member 412, and to inject a gas only toward the outer region 33 by using the gas holes 421 and the third openings 411. The gas holes 421 are not formed in the second blocking member (not shown). The second blocking region (not shown), the first blocking region 41b, and the central region 32 may be formed to have the same shape and the same size. The second blocking region (not shown) may be disposed on an inner side of the second passage region 42a. The second passage region 42a may be disposed on an outer side of the second blocking region (not shown) so as to surround the second blocking region (not shown). If the second blocking region (not shown) is formed in the shape of a circle, the second passage region 42a may be formed in the shape of a circular ring or a donut surrounding the second blocking region (not shown).

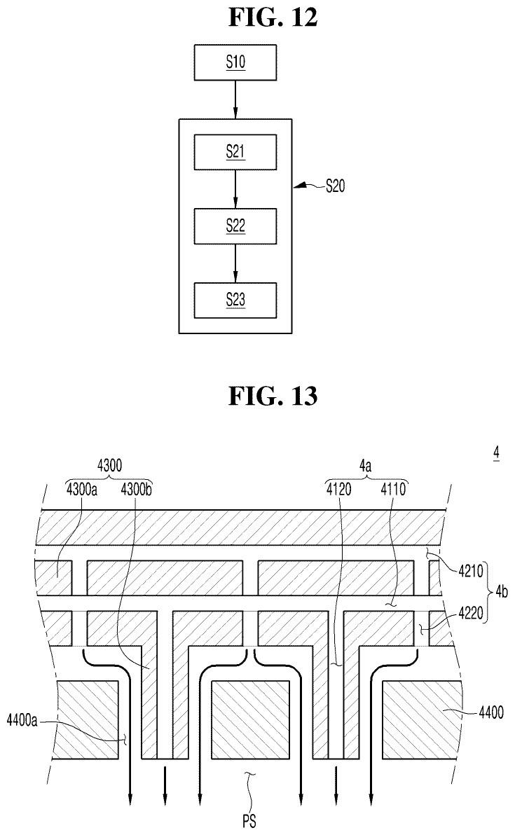

FIG. 12 is a flow chart schematically showing a method for forming the silicon carbide film in accordance with an exemplary embodiment by using the substrate processing apparatus of another exemplary embodiment.

Hereinafter, referring to (a) to (c) of FIG. 3, and FIG. 11 to FIG. 13, a method for forming the silicon carbide film in accordance with the exemplary embodiment by using a substrate processing apparatus of another exemplary embodiment will be described. Here, the description of the purge step will be omitted.

First, the temperature inside a chamber 2 is controlled to approximately 300 °C to approximately 700 °C using a heater (not shown). Then, a substrate 10 is loaded into the chamber 2, and then the substrate 10 is seated S10. The above-described step S10 may be performed by seating a plurality of substrates 10 or one substrate 10 on the substrate support part 3. The plurality of substrates 10 or the one substrate 10 may be seated on a support surface 31 of the substrate support part 3, or the plurality of substrates 10 may be seated in the outer region 33. The step S10 of seating the substrate 10 may be performed by seating the substrate 10 on the substrate support part 3 by a transfer robot (not shown) for transferring the substrate 10.

In the above description, it has been described that the temperature inside the chamber 2 is controlled and then the substrate 10 is seated on the substrate support part 3. However, the embodiment is not limited thereto, and the substrate 10 may be seated on the substrate support part 3 and then the temperature inside the chamber 2 may be controlled.

Next, a processing process is performed S20. The above step S20 may be performed by injecting a processing gas toward the substrate 10 to perform the processing process on the substrates 10. If one substrate 10 is seated, the injection part 4 may inject a gas to the front surface of the substrate 10.

In addition, in another exemplary embodiment, the injection part 4 may inject a gas only toward the outer region 33 and may not inject a gas toward the central region 32 to perform the processing process on the substrates 10.

Therefore, it is possible to reduce the flow rate of a gas flowing into the central region 32 in which the substrate 10 is not present, thereby being wasted without being involved in the above-described processing process. Accordingly, by reducing operation costs through the reduction in the flow rate of the wasted gas, it is possible to contribute to lowering manufacturing costs of the formation of the silicon carbide film 20.

In addition, if a gas is injected toward the front surface of the one substrate 10, the gas flows to the front surface of the one substrate 10 to increase the flow rate of a gas involved in the processing process, so that the uniformity of the silicon carbide film 20 formed by performing the processing process may be improved.

Here, a width H of the outer region 33 may be implemented to be equal to the diameter of the substrate 10, or to be longer than the diameter of the substrate 10. Accordingly, in the step S20 of performing the processing process, a gas may be injected only toward the outer region 33 having the width H greater than or equal to the diameter D of the substrate 10. Accordingly, the process may be implemented to inject a gas toward the front surface of one surface of the substrate 10 facing the injection part 4, with respect to all of the substrates 10 disposed in the outer region 33. Therefore, the uniformity of the processing process for each of the substrates 10 may be improved.

Here, the step S20 of performing the processing process may be performed by injecting a gas activated by using plasma. In this case, by using plasma power applied from the power supply unit 40b, the injection part 4 may generate plasma to inject the activated gas only toward the plurality of substrates or one substrate 10. Accordingly, the plasma may be used to perform crystallization, film densification, impurity removal, or the like on a thin film formed on each of the substrates 10 to further improve the quality of the substrate 10 on which the processing process is performed.

Here, the step S20 of performing the processing process may include injecting a silicon-containing gas (source gas) S21, forming first hydrogen plasma while injecting a carbon-containing gas S22, and forming second hydrogen plasma S23.

The step S21 of injecting the silicon-containing gas (source gas) may be performed by injecting a gas containing silicon to the substrates 10 disposed in the outer region 33. The above-described step S21 may be performed by injecting the silicon-containing gas only toward the outer region 33 such that a source material is adsorbed on the substrates 10. The step S21 of injecting of the silicon-containing gas may be performed by injecting the silicon-containing gas only toward the outer region 33, which is the front surface of one substrate 10 or the front surface of the plurality of substrates 10.

The injection part 4 may inject the silicon-containing gas only toward the substrate 10 through the third openings 411. The injection part 4 may inject the silicon-containing gas only through the first openings 421a among the third openings 411. The injection part 4 may inject the silicon-containing gas through the first gas flow path 4a.

In the step S22 of forming first hydrogen plasma while injecting a carbon-containing gas, a method for injecting the carbon-containing gas will be first described. The injecting of a carbon-containing gas may be performed by injecting the carbon-containing gas to the substrate 10. The above step may be performed by injecting the carbon-containing gas toward the substrate 10 to form a film (or a thin film) on the substrate 10.

In this case, a source material adsorbed on the substrate 10 through the step S21 of spaying a silicon-containing gas and the carbon-containing gas injected through the step S22 of injecting a carbon-containing gas may react with each other to form the silicon carbide film 22 on the substrate 10. In this case, the silicon carbide film 22 may be amorphous. The step S22 of injecting of a carbon-containing gas may be performed by injecting the carbon-containing gas only toward the substrate 10 by the injection part 4. In this case, the injection part 4 may inject the carbon-containing gas only toward the outer region 33 through the third openings 411.

The step S22 of forming first hydrogen plasma while injecting a carbon-containing gas includes injecting a hydrogen-containing gas. The injecting of a hydrogen-containing gas may be performed by injecting the hydrogen-containing gas to the substrate 10. The injection part 4 may inject the hydrogen-containing gas through the third openings 411. Plasma may be formed between the first plate 42 and the second plate 41. The formed hydrogen-containing gas plasma may inject a hydrogen-containing gas to the substrate 10 through the third openings 411. The injecting of the hydrogen-containing gas may be blocked by the first blocking member 412. As described above, when the hydrogen-containing gas is injected using the injection part 4, a discharge gas may be injected together.

The step S21 of injecting a silicon-containing gas may be performed by injecting the silicon-containing gas toward the substrate 10. The step S22 of injecting of a carbon-containing gas and a hydrogen-containing gas may be performed by injecting the carbon-containing gas and the hydrogen-containing gas toward the front surface of the substrate 10. The step S21 of injecting the silicon-containing gas and the step S22 of injecting the carbon-containing gas and the hydrogen-containing gas may be sequentially performed. Accordingly, after a source material of the silicon-containing gas is adsorbed on one substrate 10 or all of one or more substrates 10, an amorphous silicon carbide film 22 may be implemented to be deposited by a reaction using the carbon-containing gas and the hydrogen-containing gas substrates 10. Therefore, since it is possible to reduce process time required until a processing process is performed on all of the substrate 10, the productivity of the substrate 10 on which the processing process is completed may be increased. The formation of plasma is performed by applying RF power to one of the second plate 41 (first electrode) and the first plate 42 (second electrode) using the power supply unit 40b. At this time, the RF power may be approximately 800 W to approximately 900 W. As another example, the RF power applied to any one of the second plate 41 (first electrode) and the first plate 42 (second electrode) may be approximately 1.13 W/cm² to 1.27 W/cm² per unit area of the substrate 10.

When the RF power is applied to any one of the second plate 41 (first electrode) and the first plate 42 (second electrode) as described above, first hydrogen plasma is formed in a buffer space 43. In addition, by forming the hydrogen plasma (the first plasma) while injecting the carbon-containing gas and the hydrogen-containing gas as described above, even if the temperature inside the chamber 2 is controlled to a low temperature of approximately 300 °C to approximately 700 °C, it is possible to suppress or prevent silicon (Si) from being separated from the silicon-containing film 21. Therefore, it is possible to form the amorphous silicon carbide film 22 with a few or no defects.

Here, since the first and second plates 41 and 42 are installed inside the chamber 2, the application of the RF power to any one of the first and second plates 41 and 42 may mean applying the RF power to the chamber 2.

Next, second hydrogen plasma is formed inside the chamber 2 S23. To this end, the injection part 4 is used to inject a hydrogen-containing gas into the chamber 2, and at this time, a discharge gas may be injected together. RF power is applied to any one of the second plate 41 (first electrode) and the first plate 42 (second electrode) while the hydrogen-containing gas and the discharge gas are injected into the chamber 2 by using the injection part 4. At this time, the RF power may be approximately 800 W to approximately 900 W. As another example, the RF power applied to any one of the second plate 41 (first electrode) and the first plate 42 (second electrode) may be approximately 1.13 W/cm² to 1.27 W/cm² per unit area of the substrate 10.

When the RF power is applied to any one the second plate 41 (first electrode) and the first plate 42 (second electrode) as described above, thereby forming the second hydrogen plasma, the amorphous silicon carbide film 22 may be crystallized. That is, even if the temperature inside the chamber 2 is controlled to a low temperature of approximately 300 °C to approximately 700 °C, the amorphous silicon carbide film 22 may be crystallized by the second hydrogen plasma. Therefore, it is possible to form the crystalline silicon carbide film 20 with a few or no defects.

Referring to FIG. 13, the substrate processing apparatus of another exemplary embodiment may include the chamber 2, the substrate support part 3, and the injection part 4. In addition, the substrate processing apparatus 1 may include a heater (not shown) for heating the inside of the chamber. In this case, the heater may be connected to the chamber 2, or may be installed inside the chamber 2.

The substrate support part 3 supports the substrate 10. The substrate support part 3 may support one substrate 10, or may support a plurality of substrates 10. When the plurality of substrates 10 are supported by the substrate support part 3, a processing process may be performed on the plurality of substrates 10 at a time. The substrate support part 3 may be coupled to the chamber 2. The substrate support part 3 may be disposed inside the chamber 2, and a plurality of six substrates 10 may be disposed.

A injection part 4 injects a gas toward the substrate support part 3. The injection part 4 may be connected to a gas storage unit 40a. Accordingly, the injection part 4 may inject a gas supplied from the gas storage unit 40a toward the substrate support part 3. The injection part 4 may be coupled to the chamber 2, or may be installed to be positioned inside the chamber 2. The injection part 4 may be disposed to oppose the substrate support part 3. The processing space PS may be disposed between the injection part 4 and the substrate support part 3. The injection part 4 may be coupled to a lid. The lid is coupled to the chamber 2 to cover an upper portion of the chamber 2.

The injection part 4 may include a first gas flow path 4a, and a second gas flow path 4b.

The first gas flow path 4a is for injecting a first gas. One side of the first gas flow path 4a may be connected to the gas storage unit 40a through a pipe, a hose, or the like. The other side of the first gas flow path 4a may communicate with the processing space PS. Accordingly, the first gas supplied from the gas storage unit 40a may flow along the first gas flow path 4a and then be injected into the processing space PS through the first gas flow path 4a. The first gas flow path 4a may function as a path through which the first gas flows and may also function as an injection port for injecting the first gas into the processing space PS.

The second gas flow path 4b is for injecting a second gas. The second gas and the first gas may be gases different from each other. For example, if the first gas is a silicon-containing gas (i.e., a source gas), the second gas may be a carbon-containing gas (i.e., a reactant gas) and a hydrogen-containing gas. That is, the silicon-containing source gas may pass through the first gas flow path 4a, and the carbon-containing gas and the hydrogen-containing gas may pass through the second gas flow path 4b. As another example, if the first gas is a silicon-containing gas, the second gas may be a mixed gas containing carbon and hydrogen. In this case, the silicon-containing gas may pass through the first gas flow path 4a, and the mixed gas may pass through the second gas flow path 4b. Of course, conversely, the second gas may be a silicon-containing gas. In this case, the first gas may be a carbon-containing gas and a hydrogen-containing gas, or a mixed gas containing carbon and hydrogen.

One side of the second gas flow path 4b may be connected to the gas storage unit 40a through a pipe, a hose, or the like. The other side of the second gas flow path 4b may communicate with the processing space PS. Accordingly, the second gas supplied from the gas storage unit 40a may flow along the second gas flow path 4b and then be injected into the processing space PS through the second gas flow path 4b. The second gas flow path 4b may function as a path through which the second gas flows and may also function as an injection port for injecting the second gas into the processing space PS. In this case, the second gas supplied from the gas storage unit 40a may flow along the second gas flow path 4b and then hit an upper surface of a second electrode 4400 to be described later, and be injected between holes 4400a, thereby being injected into the processing space PS. As a result, the flow of a gas may be increased to allow a deposition film to be uniform. The second gas flow path 4b may function as a path through which the second gas flows and may also function as an injection port for injecting the second gas into the processing space PS.

The second gas flow path 4b and the first gas flow path 4a may be disposed to be spatially separated from each other. Accordingly, the second gas supplied from the gas storage unit 40a to the second gas flow path 4b may be injected into the processing space PS without passing through the first gas flow path 4a. The first gas supplied from the gas storage unit 40a to the first gas flow path 4a may be injected into the processing space PS without passing through the second gas flow path 4b. The second gas flow path 4b and the first gas flow path 4a may inject a gas toward different portions in the processing space PS.

Referring to FIG. 14, the injection part 4 may include a first electrode 4300 and a second electrode 4400. In this case, since the first electrode 4300 and the second electrode 4400 are disposed in a vertical direction, and the first electrode 4300 is positioned on an upper side of the second electrode 4400, the first electrode 4300 may be an upper electrode, and the second electrode 4400 may be a lower electrode. In addition, the first electrode 4300 or the upper electrode may be referred to as a first plate, and the second electrode 4400 or the lower electrode may be referred to as a second plate.

The first electrode 4300 may be disposed on an upper side of the substrate support part 3 to oppose the substrate support part 3. The first electrode 4300 may serve as a ground electrode by being grounded. The first electrode 4300 may include the first gas flow path 4a and the second gas flow path 4b. Accordingly, the first electrode 4300 may inject the first gas through the first gas flow path 4a, and may inject the second gas through the second gas flow path 4b. The first gas flow path 4a and the second gas flow path 4b may be disposed to be spatially separated from each other inside the first electrode 4300.

The first gas flow path 4a may include a first connection hole 4110 connected to the gas storage unit 40a and a plurality of first injection holes 4120 connected to the first connection hole 4110. The first connection hole 4110 and the first injection holes 4120 may be formed inside the first electrode 4300. One side of the first injection holes 4120 may communicate with the first connection hole 4110, and the other side thereof may communicate with the processing space PS. Accordingly, the first gas supplied from the gas storage unit 40a may flow along the first connection hole 4110 and then be injected into the processing space PS through the first injection holes 4120.

The second gas flow path 4b may include a second connection hole 4210 connected to the gas storage unit 40a and a plurality of second injection holes 4220 connected to the second connection hole 4210. The second connection hole 4210 and the second injection holes 4220 may be formed inside the first electrode 4300. One side of the second injection holes 4220 may communicate with the second connection hole 4210, and the other side thereof may communicate with the processing space PS. Accordingly, the second gas supplied from the gas storage unit 40a may flow along the second connection hole 4210 and then be injected into the processing space PS through the second injection holes 4220.

The first electrode 4300 may include a base member 4300a extending in a direction in which the substrate support part 3 extends and a protruding member 4300b extending downward in a protruding manner from a lower surface of the base member 4300a. The protruding member 4300b may have a shape extending from the lower surface of the base member 4300a in a direction in which the substrate support part 3 is positioned. The above-described protruding member 4300b may be provided in plurality, and the plurality of protruding members 4300b may be disposed to be spaced apart from each other.

If the first electrode 4300 includes the base member 4300a and the protruding member 4300b, each of the first connection hole 4110, the second connection hole 4210, and the second injection hole 4220 may be provided in the base member 4300a. In this case, the first and second connection holes 411 and 421 may have a shape, for example, extending in a direction in which the base member 4300a extends. In addition, the second injection hole 4220 may extend in a vertical direction, and one end thereof may be connected to the second connection hole 4210 and the other end thereof may communicate with the processing space PS. In addition, the first injection hole 4120 of the first gas flow path 4a may be provided to extend from the base member 4300a to the protruding member 4300b. That is, the first injection hole 4120 may be provided by passing through the protruding member 4300b in the vertical direction, and one end in the extension direction may be connected to the first connection hole 4110 and the other end in the extension direction may communicate with the processing space PS. Since the first connection hole 4110 is provided in the base member 4300a, the first injection hole 4120 may be connected to the first connection hole 4110 by passing through a portion of the base member 4300a in the vertical direction.

The second electrode 4400 may include the hole 4400a provided to allow the protruding member 4300b to be inserted thereinto. The hole 4400a may be formed by passing through the second electrode 4400. The above-described hole 4400a may serve as a flow path which allows a gas discharged from the first electrode 4300 to pass therethrough. The hole 4400a may be formed in the same number as the protruding member 4300b, and the hole 4400a may be formed at a position facing the protruding member 4300b. Then, the protruding member 4300b may be inserted into each of a plurality of the holes 4400a. The inner diameter (or width) of the hole 4400a may be larger than the diameter (or width) of the protruding member 4300b, and the length in a vertical direction of the hole 4400a may be smaller than the length in a vertical direction of the protruding member 4300b.

When the protruding member 4300b of the first electrode 4300 is inserted into the hole 4400a formed in the second electrode 4400, the insertion is performed such that the height of a lower surface of the protruding member 4300b is equal to the height of a lower surface of the second electrode 4400. Thus, a lower surface of the base member 4300a and an upper surface of the second electrode 4400 are spaced apart from each other, and the separation space communicates with the second injection hole 4220. In addition, when the protruding member 4300b of the first electrode 4300 is inserted into the hole 4400a of the second electrode 4400, the insertion is performed such that an outer surface of the protruding member 4300b is spaced apart from an inner surface of the second electrode 4400 surrounding the hole 4400a. Thus, an outer space of the protruding member 4300b in the hole 4400a communicates with the separation space between the lower surface of the base member 4300a and the upper surface of the second electrode 4400. In addition, the outer space of the protruding member 4300b in the hole 4400a communicates with the processing space PS. Therefore, a gas discharged from the second injection hole 4220 may pass through the hole 4400a provided in the second electrode 4400 and be injected toward the substrate support part 3. That is, the second gas discharged from the second injection hole 4220 may pass through the separation space between the lower surface of the base member 4300a and the upper surface of the second electrode 4400, and then may pass through the hole 4400a provided in the second electrode 4400 to be injected toward a lower side of the hole 4400a. In this case, in passing through the hole 4400a, the second gas passes along the outer space of the protruding member 4300b.

The second electrode 4400 is disposed between the first electrode 4300 and the substrate support part 3. The second electrode 4400 may be spaced apart from the first electrode 4300 and disposed on a lower side of the first electrode 4300. An insulation member (not shown) for partial insulation may be disposed between the second electrode 4400 and the first electrode 4300. RF power may be applied to the second electrode 4400. When the first electrode 4300 is grounded and the RF power is applied to the second electrode 4400, plasma may be generated. That is, plasma may be generated in a space between the first electrode 4300 and the second electrode 4400. More specifically, plasma may be generated in the separation space between the lower surface of the base member 4300a and the upper surface of the second electrode 4400 and in the hole 4400a. In addition, a gas may be activated using the plasma formed as described above, and the activated gas may be injected to the processing space PS.

In the above description, it has been described that the first electrode 4300 is grounded and the RF power is applied to the second electrode 4400 to form plasma. However, the embodiment is not limited thereto, and RF power may be applied to the first electrode 4300 and the second electrode 4400 may be grounded to form plasma. In addition, a positive(+) voltage may be applied to any one of the first electrode 4300 and the second electrode 4400, and a negative(−) electrode may be connected to the other electrode to form plasma.

Referring to FIG. 13, the hole 4400a and the protruding member 4300b are formed in the entire region of a lower surface of the injection part 4. In other words, the hole 4400a and the protruding member 4300b are formed in an outer region of a central region in the injection part 4, and rather than the hole 4400a and the protruding member 4300b not being formed in the central region, the hole 4400a and the protruding member 4300b are formed over the entire region of the injection part 4. Thus, the injection part 4 may inject a gas to the entire region of the substrate support part 4.

In the above description, it has been described that the first electrode 4300 includes the base member 4300a and the protruding member 4300b extending toward a lower portion of the base member 4300a. Thus, the height of a lower surface of the protruding member 4300b is lower than the height of a lower surface of the base member 4300a. In this case, a lower surface of the first electrode 4300 is not flat, and the height thereof is different for each position.

However, the first electrode 4300 is not limited thereto, and may not include the protruding member 4300b. That is, the first electrode 4300 may include only the base member 4300a, and may not include the protruding member 4300b extending downward from the base member 4300a. In this case, the lower surface of the first electrode 4300 may have a flat shape.

When each of a lower surface of the second electrode 4400 and an upper surface of the first electrode 4300 is formed to be flat, some the holes 4400a may be disposed at a position corresponding to the first gas flow path 4a to allow the first gas injected from the first gas flow path 4a to pass therethrough. The other remaining holes 4400a may be disposed at a position corresponding to the second gas flow path 4b to allow the second gas injected from the second gas flow path 4b to pass therethrough. Although not illustrated, in the second electrode 4400, the holes 4400a may be formed in a number smaller than the sum of the number of first injection holes 4120 of the first gas flow path 4a and the number of second injection holes 4220 of the second gas flow path 4b.

In addition, if the second electrode 4400 includes a plurality of protruding members 4300b as illustrated in FIG. 14, the holes 4400a may be formed at positions respectively corresponding to the protruding members 4300b in the second electrode 4400. The protruding members 4300b may protrude toward the substrate support part 3. The protruding members 4300b may protrude from the lower surface of the first electrode 4300 and be inserted into each of the holes 4400a. The first gas flow path 4a may be provided in the inside of each of the protruding members 4300b. In this case, the first injection holes 4120 may be formed such that one side thereof is connected to the first connection hole 4110 and the other side thereof passes through the protruding members 4300b.

Hereinafter, referring to FIG. 3, FIG. 6, FIG. 13, and FIG. 14, a method for forming a silicon carbide film of another exemplary embodiment by using a third substrate processing apparatus will be described.

First, the temperature inside a chamber 2 is controlled to approximately 300 °C to approximately 600 °C using a heater (not shown). Then, a substrate 10 is loaded into the chamber 2, and then the substrate 10 is seated on a substrate support part 3.

Next, a silicon-containing gas is injected toward the substrate support part 3 by using an injection part 4. To this end, the silicon-containing gas is supplied to a first connection hole 4110 of the injection part 4 by using a gas storage unit 40a. Thus, the silicon-containing gas supplied to the first connection hole 4110 passes through a first injection hole 4120 formed in a protruding member 4300b and is injected toward the substrate support part 3. Thus, the silicon-containing gas is adsorbed or deposited on the substrate 10 seated on the substrate support part 3, thereby forming a silicon-containing film 21 as shown in (a) of FIG. 3.

Thereafter, a purge gas is supplied into the chamber 2, thereby purging the chamber 2 (primary purge).

After the primary purge is completed, a carbon-containing gas is injected using the injection part 4 to generate first hydrogen plasma. To this end, the carbon-containing gas and a hydrogen-containing gas are supplied to a second connection hole 4210 of the injection part 4 by using the gas storage unit 40a. In this case, it is more effective to supply a discharge gas, for example, an argon gas, to the second connection hole 4210. Thus, the carbon-containing gas, the hydrogen-containing gas, and the discharge gas supplied to the second connection hole 4210 pass through a second injection hole 4220 and then are introduced into a separation space between a base member 4300a and a second electrode 4400. That is, the carbon-containing gas, the hydrogen-containing gas, and the discharge gas are introduced into the separation space between the base member 4300a and an upper surface of the second electrode 4400 and into a hole 4400a.

As described above, while a gas passes through a space between a first electrode 4300 and the second electrode 4400, RF power is applied to the second electrode 4400. Thus, the gas passing through the space between the first electrode 4300 and the second electrode 4400 is discharged, thereby forming plasma, and the plasma may be hydrogen plasma. Once the hydrogen plasma is formed, the carbon-containing gas is activated. Then, the activated carbon-containing gas is injected toward the substrate 10 disposed on a lower side of the hole 4400a. Thus, the silicon-containing film 21 formed on the substrate 10 reacts with the carbon-containing gas, thereby forming the amorphous silicon carbide film 22 as illustrated in (b) of FIG. 3.

In forming the first hydrogen plasma, the RF power applied to the second electrode 4400 is controlled. In this case, the RF power applied to the second electrode 4400 may be approximately 800 W to approximately 900 W. As another example, the RF power applied to the second electrode 4400 may be approximately 2.66 W/cm² to approximately 3 W/cm² per unit area of the substrate 10.

Next, second hydrogen plasma is formed inside the chamber 2. To this end, the hydrogen-containing gas is supplied to the second connection hole 4210 of the injection part 4 by using the gas storage unit 40a. In this case, it is more effective to supply a discharge gas, for example, an argon gas, to the second connection hole 4210. Thus, the hydrogen-containing gas and the discharge gas supplied to the second connection hole 4210 pass through the second injection hole 4220 and then are introduced into the separation space between the base member 4300a and the second electrode 4400. That is, the hydrogen-containing gas and the discharge gas are introduced into the separation space between the base member 4300a and the upper surface of the second electrode 4400 and into the hole 4400a.

Then, while a gas passes through a space between the first electrode 4300 and the second electrode 4400, the RF power is applied to the second electrode 4400. Thus, the gas passing through the space between the first electrode 4300 and the second electrode 44 is discharged, thereby forming the second hydrogen plasma. The second hydrogen plasma crystallizes the silicon carbide film 22 formed on the substrate 10, thereby forming a crystalline silicon carbide film 20.

The RF power applied to the second electrode to form the second hydrogen plasma may be approximately 800 W to approximately 900 W. As another example, the RF power applied to the second electrode 4400 may be approximately 11.13 W/cm² to approximately 1.27 W/cm² per unit area of the substrate 10. In this case, the time for forming the second hydrogen plasma may be longer than the time for forming the first hydrogen plasma. That is, the time for forming the first hydrogen plasma while injecting the carbon-containing gas may be approximately 1 second to approximately 3 seconds, and the time for forming the second hydrogen plasma may be approximately seconds to approximately 20 seconds.

According to the exemplary embodiments, it is possible to form a crystalline silicon carbide film at a lower temperature than in the related art. That is, since a silicon carbide film is formed by generating hydrogen plasma, the silicon carbide film may be formed at a low temperature. Thus, it is possible to form a crystalline silicon carbide film with a few or no defects as compared with the related art. Therefore, in a semiconductor device including a silicon carbide film, for example, a power semiconductor device, it is possible to suppress or prevent the occurrence of a leakage current due to the silicon carbide film.

### Industrial Applicability

According to exemplary embodiments of the present inventive concept, it is possible to form a crystalline silicon carbide film at low temperatures. That is, it is possible to form a crystalline silicon carbide film with a few or no defects.

1. A method for forming a silicon carbide film on a substrate accommodated in a chamber, the method comprising:
injecting a silicon (Si)-containing gas into the chamber;
forming first hydrogen plasma inside the chamber while injecting a carbon (C)-containing gas into the chamber, thereby forming an amorphous silicon carbide film on the substrate; and
forming second hydrogen plasma inside the chamber, thereby crystallizing the amorphous silicon carbide film.

2. The method of claim 1, wherein the forming of the first and second hydrogen plasma comprises supplying a hydrogen-containing gas into the chamber, wherein the first and second hydrogen plasma is direct plasma formed by discharging the hydrogen-containing gas inside the chamber.

3. The method of claim 2, wherein the forming of the first and second hydrogen plasma comprises supplying an argon (Ar) into the chamber.

4. The method of claim 2, wherein the forming of the first and second hydrogen plasma comprises supplying RF power to the chamber, wherein the RF power is approximately 800 W to approximately 900 W.

5. The method of claim 2, wherein the forming of the first and second hydrogen plasma comprises supplying RF power to the chamber, wherein the RF power is approximately 2.66 W/cm² to approximately 3 W/cm² per unit area of the substrate.

6. The method of claim 4, wherein in the forming of the first and second hydrogen plasma, the forming is performed by using a potential difference between a first electrode and a second electrode installed inside the chamber.

7. The method of claim 1, wherein the time for forming the second hydrogen plasma is longer than the time for forming the first hydrogen plasma.

8. The method of claim 1, wherein in the injecting of the silicon (Si)-containing gas, the forming of the amorphous silicon carbide film, and the crystallizing of the amorphous silicon carbide film, the temperature inside the chamber is controlled to approximately 300 °C to approximately 700 °C.

9. The method of claim 1, further comprising forming hydrogen plasma inside the chamber between the injecting of the silicon (Si)-containing gas and the forming of the first hydrogen plasma while injecting the carbon (C)-containing gas.

10. The method of claim 1, further comprising at least one of a purge step of injecting a purge gas into the chamber, thereby purging the inside of the chamber, and a pumping step of discharging the gas inside the chamber to the outside, thereby lowering the pressure inside the chamber, wherein at least one of the purge step and the pumping step is performed between the injecting of the silicon (Si)-containing gas and the forming of the first hydrogen plasma while injecting the carbon (C)-containing gas.

11. The method of claim 1, further comprising at least one of a purge step of injecting a purge gas into the chamber, thereby purging the inside of the chamber, and a pumping step of discharging the gas inside the chamber to the outside, thereby lowering the pressure inside the chamber, wherein at least one of the purge step and the pumping step is performed after completing the forming of the second hydrogen plasma inside the chamber, thereby crystallizing the amorphous silicon carbide film.

12. A method for forming a silicon carbide film on a substrate accommodated in a chamber including a dome-shaped upper body having an inclined surface whose height increases toward a center in a width direction and a dome-shaped lower body having an inclined surface whose height decreases toward the center in the width direction, the method comprising:
injecting a silicon (Si)-containing gas into the chamber by using a first gas injection part connected to the chamber;
forming first hydrogen plasma inside the chamber while injecting a carbon (C)-containing gas into the chamber by using a second gas injection part connected to the chamber, thereby forming an amorphous silicon carbide film on the substrate; and
forming second hydrogen plasma inside the chamber, thereby crystallizing the amorphous silicon carbide film.

13. A method for forming a silicon carbide film on a substrate accommodated in a chamber, the method comprising:
injecting a silicon (Si)-containing gas into the chamber through a first gas flow path provided in a first electrode installed in the chamber;
forming first hydrogen plasma between the first electrode and a second electrode while injecting a carbon (C)-containing gas into the chamber through a second gas flow path provided in the second electrode installed in the chamber, thereby forming an amorphous silicon carbide film on the substrate; and
forming second hydrogen plasma between the first electrode and the second electrode, thereby crystallizing the amorphous silicon carbide film.

14. (canceled)

15. (canceled)

16. (canceled)

17. (canceled)

18. (canceled)

19. (canceled)
